(19) United States
(12) Patent Application Publication
(10) Pub. No.: US 2013/0122610 A1
(43) Pub. Date: May 16, 2013

(54) Apparatus and Method for Die Bonding

(71) Applicants: Jun-Wei Chung, Yangmei City (TW); Wei-Cheng Lou, Yangmei City (TW); Jung-Kun Wu, Yangmei City (TW); Chung-I Chiang, Yangmei City (TW)

(72) Inventors: Jun-Wei Chung, Yangmei City (TW); Wei-Cheng Lou, Yangmei City (TW); Jung-Kun Wu, Yangmei City (TW); Chung-I Chiang, Yangmei City (TW)

(73) Assignee: WALSIN LIHWA CORPORATION, Yangmei City (TW)

(21) Appl. No.: 13/460,901

(22) Filed: May 1, 2012

(30) Foreign Application Priority Data
Nov. 15, 2011 (TW) 100141509

(51) Int. Cl. H01L 21/66; B32B 41/00; B32B 38/18

(52) U.S. Cl. 438/7; 156/539; 156/379; 257/E21.53

(57) ABSTRACT

A die bonding apparatus and a die bonding method are provided, which are capable of simultaneously bonding a plurality of dies from a first placement area onto a substrate disposed on a second placement area. The die bonding apparatus includes a die sucking device which is movably located above the first placement area and a second placement area. The die sucking device includes a plurality of nozzles. The nozzles can suck the dies disposed on the first placement area, and then simultaneously bond the dies onto the substrate.

This application claims priority to Taiwan Patent Application No. 100141509 filed on Nov. 15, 2011, the disclosure of which is incorporated herein by reference in its entirety.

### CROSS-REFERENCES TO RELATED APPLICATIONS

Not applicable.

### BACKGROUND OF THE INVENTION

1. Field of the Invention

The present invention provides a die bonding apparatus and a die bonding method, and more particularly, to a die bonding apparatus and a die bonding method capable of simultaneously bonding a plurality of dies.

Descriptions of the Related Art

In recent years, light emitting diodes (LEDs) have become the major development focus of green light sources in the future because of their advantages, such as energy-saving and long service life. Currently, the packaging process of LEDs usually uses a single sucking device having to suck an LED die from an adhesive film and then place the LED die onto a substrate (or a base) one by one so as to complete the die bonding process of the LED. Then, wire bonding and encapsulating process are subsequently carried out to further complete the manufacturing of the whole package.

The aforesaid die bonding process is the conventional sequential die bonding method. The LED dies are sucked and bonded one by one in the sequential die bonding method; therefore, it takes a very long time to bond all the dies. Some improved solutions have been proposed successively in the art to solve this problem. As an example, Taiwan Patent No. TW I327344 discloses a die bonding process, which divides a die bonding process into a pre-bonding stage and a primary bonding stage and the overall speed of die bonding could be improved by simultaneously bonding a plurality of dies in the time-consuming primary bonding stage. However, the time-consuming sequential die bonding method is still adopted the pre-bonding stage of the die bonding process, and this two-stage bonding process is not suitable for all LED die bonding processes.

Taiwan Patent Publication No. TW 200947641 discloses a die bonding apparatus which eliminates the use of the die sucking device. The die bonding apparatus utilizes a lifting pin unit to lift a die directly and transfer the die onto the bonding surface of a substrate so that the die is bonded to the substrate. Although this die bonding method can save the operation time of the sucking device to speed up the die bonding process, it still belongs to a sequential die bonding method. In addition, the accuracy of the die bonding process is significantly degraded by eliminating the use of the die sucking device.

Furthermore, Taiwan Patent Publication No. TW 200952211 discloses another die bonding method. Apart from eliminating the use of the die sucking device, this die bonding method also adopts a process of simultaneously bonding a plurality of dies; therefore, the die bonding speed can be remarkably increased. However, because the use of the die sucking device is eliminated, it is difficult to be used in precise die bonding processes.

Therefore, adopting the sequential die bonding method in the die bonding process is apparently very time-consuming, and even though eliminating the use of the die sucking device can increase the speed of the die bonding, it is unsuitable for precise die bonding processes.

Accordingly, the major development objective in the art is to provide a die bonding apparatus and a die bonding method capable of overcoming at least one of the aforesaid drawbacks.

### SUMMARY OF THE INVENTION

The primary objective of the present invention is to provide a die bonding apparatus and a die bonding method capable of simultaneously bonding a plurality of dies onto a substrate.

To achieve the aforesaid objective, the present invention discloses a die bonding apparatus. The die bonding apparatus comprises a die sucking device, which is movably located above a first placement area and a second placement area. The die sucking device comprises a plurality of nozzles, which are used for sucking a predetermined number of dies disposed on the first placement area and then simultaneously placing the predetermined number of dies onto the substrate.

To achieve the aforesaid objective, the present invention further discloses a die bonding apparatus, comprising: a die bearing plate; a first die sucking device movably located above a first placement area and the die bearing plate, wherein the first die sucking device comprises a first nozzle; and a second die sucking device movably located above a second placement area and the die bearing plate, wherein the second die sucking device comprises a plurality of second nozzles. The first nozzle is used for sucking one of the dies disposed on the first placement area and aiming at the die bearing plate to place the sucked die onto the die bearing plate until the first die sucking device has placed a predetermined number of dies onto the die bearing plate. The second nozzles are used for simultaneously sucking the predetermined number of the dies disposed on the die bearing plate and simultaneously placing the predetermined number of the dies onto the substrate.

To achieve the aforesaid objective, the present invention further discloses a die bonding method, comprising the following steps: moving a die sucking device to aim at one of the dies disposed on a first placement area and then to suck the one of the dies; repeating the above step until the die sucking device has sucked a predetermined number of dies; and moving the die sucking device to simultaneously place the predetermined number of dies onto the substrate disposed on a second placement area.

To achieve the aforesaid objective, the present invention further discloses a die bonding method, comprising the following steps: moving a die sucking device having a plurality of nozzles to suck a predetermined number of the dies disposed on a first placement area; driving the nozzles to orientate the predetermined number of the dies sucked by the nozzles; and moving the die sucking device to simultaneously place the predetermined number of dies onto the substrate disposed on a second placement area.

To achieve the aforesaid objective, the present invention further discloses a die bonding method, comprising the following steps: moving a first die sucking device to suck one of the dies disposed on a first placement area; aiming at a predetermined area of a die bearing plate and placing the sucked die onto the predetermined area of the die bearing plate; repeating the above steps until the first die sucking device has placed a predetermined number of dies onto the die bearing plate; and moving a second die sucking device to simultaneously suck the predetermined number of dies disposed on the die bearing plate and simultaneously place the predetermined number of dies onto the substrate disposed on a second placement area.

Thereby, the die bonding apparatus and the die bonding method of the present invention can provide a fast die bonding speed due to the simultaneous bonding of a plurality of dies and a desirable bonding accuracy due to the use of a die sucking device. In addition, the drawbacks of the conventional sequential die bonding process, in which the process is time-consuming and inaccurate, can be overcome. Furthermore, the steps of repeated heating as required in the conventional die bonding process is reduced, and the thermal budget accumulated by the dies could be reduced thereby.

The detailed technology and preferred embodiments implemented for the subject invention are described in the following paragraphs accompanying the appended drawings for people skilled in this field to well appreciate the features of the claimed invention.

### BRIEF DESCRIPTION OF THE DRAWINGS

FIG. 1A is a schematic view of a die bonding apparatus according to a first preferred embodiment of the present invention;

FIG. 1B is a flowchart diagram of a die bonding method according to the first preferred embodiment of the present invention;

FIG. 2A is a schematic view of a die bonding apparatus according to a second preferred embodiment of the present invention;

FIG. 2B is a flowchart diagram of a die bonding method according to the second preferred embodiment of the present invention;

FIG. 3A is a schematic view of a die bonding apparatus according to a third preferred embodiment of the present invention; and

FIG. 3B is a flowchart diagram of a die bonding method according to the third preferred embodiment of the present invention.

### DESCRIPTION OF THE PREFERRED EMBODIMENT

Hereinbelow, the die bonding apparatus and the die bonding method of the present invention will be described with reference to embodiments thereof. However, it shall be appreciated that the attached drawings are depicted in a slightly simplified or slightly exaggerative way to facilitate the understanding of the present invention. The numbers, shapes and dimensional scales of elements shown in the attached drawings are unnecessarily the same as those in actual implementations and are not intended to limit the present invention.

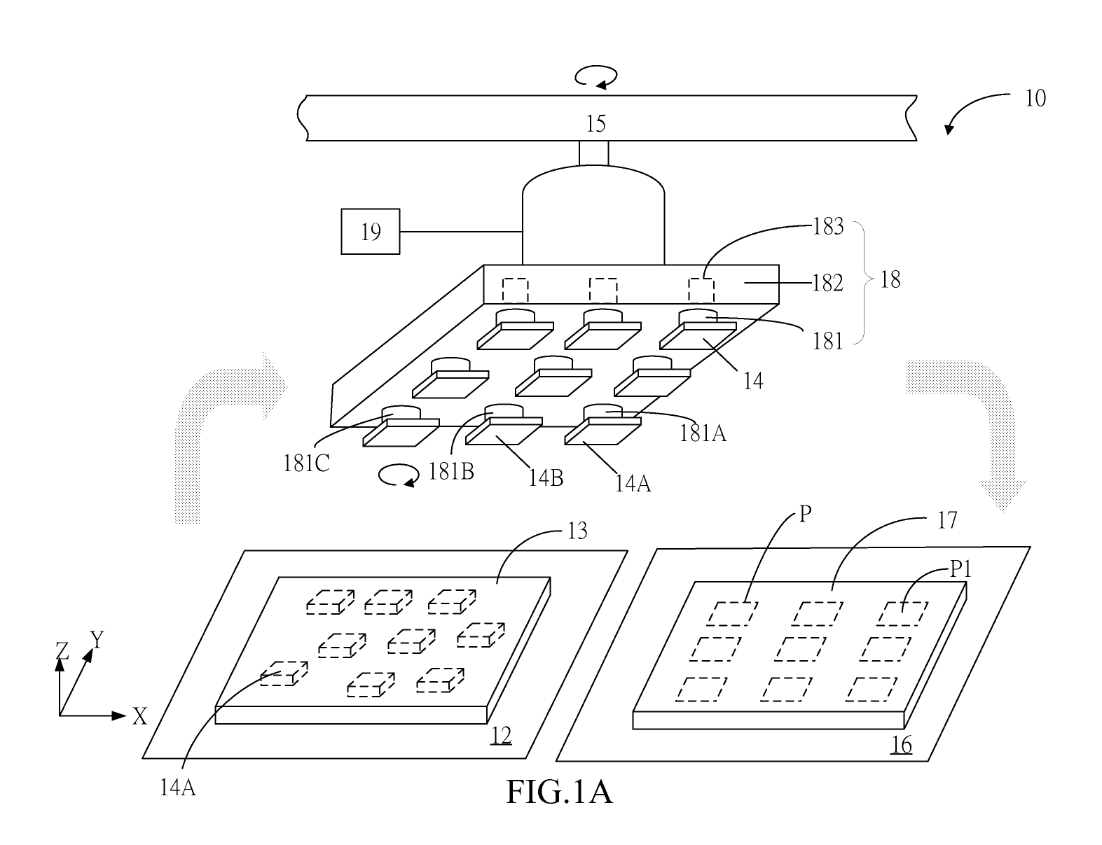

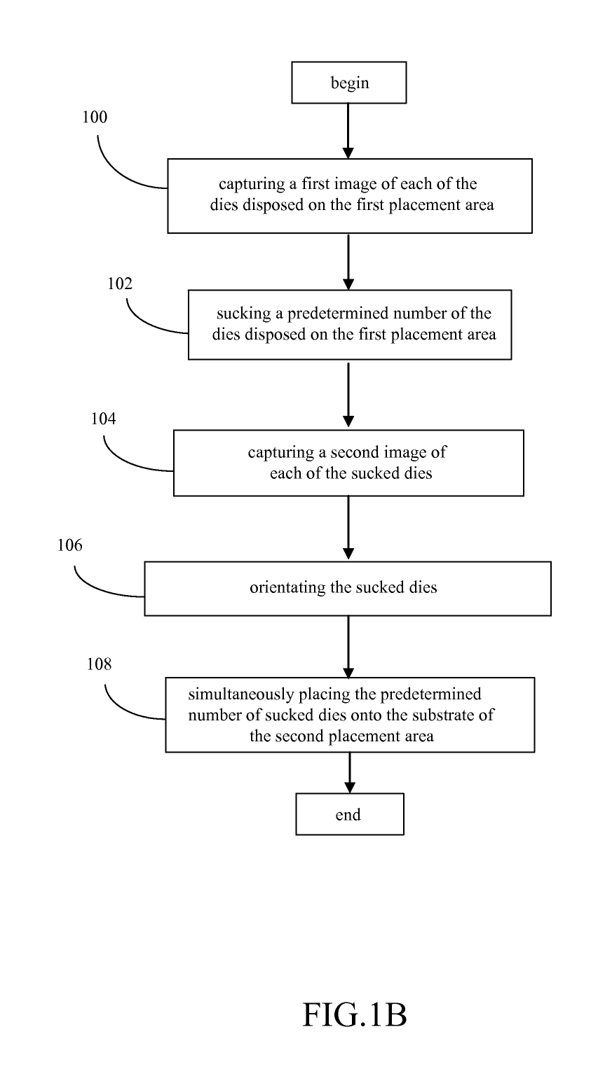

First, FIG. 1A illustrates a schematic view of a die bonding apparatus 10 according to a first preferred embodiment of the present invention. The feature of the bonding apparatus 10 of this embodiment is that it can suck a plurality of dies simultaneously, sequentially, or partially simultaneously and partially sequentially, and finely adjust the relative positions among the dies to accurately position the dies before simultaneously bonding the dies onto the substrate.

More specifically, the die bonding apparatus 10 comprises a die sucking device 18 having a plurality of nozzles 181. The die sucking device 18 is movably located above a first placement area 12 and a second placement area 16, such that the nozzles 181 of the die sucking device 18 can move to the above of the first placement area 12 and the second placement area 16 to suck a predetermined number of dies 14 from the first placement area 12 simultaneously, sequentially, or partially simultaneously and partially sequentially and then simultaneously place the dies 14 onto the substrate 17. In this way, the die bonding apparatus 10 can transfer the predetermined number of dies 14 from an adhesive film 13 disposed on the first placement area 12 to the substrate 17 disposed on the second placement area 16.

Additionally, it shall be particularly appreciated that the predetermined number of the dies described herein is equal to the number of the nozzles of the die sucking device. For example, if the die sucking device has nine nozzles, then the predetermined number of the dies is nine.

Furthermore, the concrete operations of sucking a plurality of dies simultaneously, sequentially, or partially simultaneously and partially sequentially by the die bonding apparatus 10 will be described as follows. The dies 14 disposed on the adhesive film 13 disposed on the first placement area 12 are not always arranged regularly and sometimes comprise vacant positions therebetween, so sometimes the predetermined number of the dies 14 cannot be sucked by the die bonding apparatus 10 at once but could be sucked by several times. Taking the die bonding apparatus 10 of this embodiment as an example, the die sucking device 18 having nine nozzles 181 sometimes can suck nine dies 14 at once, but sometimes only can suck five dies 14 and then suck one to four dies 14 sequentially to make the number of sucked dies 14 up to nine.

The die sucking device 18 further comprises a main body 182, a plurality of aiming devices 183 and a pneumatic control unit (e.g., a pneumatic control device comprising components such as a pneumatic valve, an air operated valve, an air motor, a controller and an actuator; not shown). In this embodiment, the nozzles 181 are disposed on one side of the main body 182, and the aiming devices 183 are disposed inside the main body 182 and respectively coupled to the nozzles 181. Each of the aiming devices 183 may be used for moving and/or rotating the coupled nozzle 181 respectively. Additionally, the pneumatic control unit is connected with the nozzles 181 to keep or release the suction of the nozzles 181, such that the nozzles 181 can suck or release the dies 14.

In this embodiment, the die 14 may be a light emitting diode (LED) die, a solar cell die, or some other non-encapsulated semiconductor component; the adhesive film 13 may be a blue tape, an adhesive film used in the electronic industries, or an adhesive plastic film for bearing the dies; and the substrate 17 may be a plastic substrate, a glass substrate, a silicon substrate, a ceramic substrate, a printed circuit board (PCB), or a flexible substrate with a circuit pattern.

The substrate 17 has a plurality of die bonding areas P defined thereon, each of which has a predetermined position and a predetermined orientation. When the dies 14 are disposed on the die bonding areas P according to the respective predetermined positions and predetermined orientations, the dies 14 can be electrically connected to the substrate 17 precisely.

The individual components of the die bonding apparatus 10 will be further described as follows.

As described above, the die sucking device 18 can move to the above of the first placement area 12 and the second placement area 16. The die sucking device 18 may be moved in various ways, and in this embodiment, the die sucking device 18 is moved by a moving device 15 (e.g., a robotic arm, or a driving motor in combination with a screw). The moving device 15 is connected to the die sucking device 18 to change the horizontal position of the die sucking device 18 by driving it to move in the X and Y directions and to change the vertical position of the die sucking device 18 by driving it to move in the Z direction.

For purposes of further describing the operating mode of the nozzles 181 of the die sucking device 18 in details, three of the nozzles 181 are named as the first nozzle 181A, second nozzle 181B and third nozzle 181C respectively, as shown in FIG. 1A. The number of nozzles 181 of the die sucking device 18 may be depended on practical needs.

Each of the aiming devices 183 is connected with respective nozzle 181 to separately move and/or rotate the nozzle 181. In other words, when one of the nozzles 181 (e.g., the first nozzle 181A) is moved or rotated separately, other nozzles 181 (e.g., the second nozzle 181B and the third nozzle 181C) will not move or rotate together. The aiming devices 183 may be implemented in various ways. For example, each of the aiming devices 183 may include a base that can move in the X and the Y directions, a motor and a number of transmission gears (not shown). The motor is fixed on a pedestal to drive the transmission gears so that the nozzles 181 are moved in parallel or rotated. It shall be appreciated that the aiming devices 183 may also be implemented by other conventional aiming devices capable of moving the nozzles 181 in a parallel way and rotating the nozzles 181, and the present invention has no limitation on these implementations.

In addition to the aforesaid components, the die bonding apparatus 10 may further comprise an image capturing device 19. The image capturing device 19 may be electrically connected to the die sucking device 18 and move relative to the die sucking device 18. The image capturing device 19 may be any electronic device capable of capturing a digital image such as a camera or video camera device.

The image capturing device 19 can capture a first image of each of the dies 14 on the adhesive film 13 before the nozzles 181 suck the dies 14. After the first image is captured, an initial position of each of the dies 14 on the adhesive film 13 can be obtained through an image processing and recognizing technology.

The image capturing device 19 may further capture a second image of each of the sucked dies 14 after the dies 14 are sucked by the nozzles 181. After the second image is captured, the current position and current orientation of each of the sucked dies 14 can be analyzed through an image processing and recognizing technology to further determine the differences between the current position and orientation of each of the dies 14 and the predetermined position and orientation of the corresponding die bonding area P. In other words, the differences include a position difference and an orientation difference.

After the position and orientation differences are obtained, each of the aiming devices 183 can move and/or rotate the respective nozzle 181 according to the position and orientation differences to adjust the position and orientation of each of the sucked dies 14. After being adjusted, the position and orientation of each of the sucked dies 14 will become consistent with the predetermined position and the predetermined orientation of the corresponding die bonding area P.

It shall be appreciated that if only a position difference exists but without orientation difference exists between one of the sucked dies 14 and the corresponding die bonding area P, then the aiming device 183 only needs to move but doesn't need to rotate the corresponding nozzle 181. On the contrary, if only an orientation difference exists between one of the sucked dies 14 and the corresponding die bonding area P, then the aiming device 183 only needs to rotate the corresponding nozzle 181.

FIG. 1B illustrates an operating method of the die bonding apparatus 10, which is also the die bonding method according to the first preferred embodiment of the present invention. The die bonding method comprises the following steps.

Step 100: capturing the first image of each of the dies 14 disposed on the first placement area 12 to obtain an initial position of each of the dies 14 on the first placement area 12.

In detail, before the dies 14 on the adhesive film 13 of the first placement area 12 are sucked by the die sucking device 18, the image capturing device 19 can capture the first image of each of the dies 14 to obtain the initial position of each of the dies 14 scattered on the first placement area 12. The initial position is used as a reference index for the die sucking device 18 when subsequently driving and positioning the nozzles 181 to aim at the sucked dies 14.

Step 102: moving the die sucking device 18 to suck a predetermined number of dies 14 disposed on the first placement area 12.

In detail, the die sucking device 18 will move above the first placement area 12 according to the initial position of each of the dies 14 so that each of the nozzles 181 (e.g., the first nozzle 181A) sucks one of the dies 14 (e.g., the first die 14A) disposed on the first placement area 12 simultaneously, sequentially, or partially simultaneously and partially sequentially.

Step 104: capturing a second image of each of the sucked dies 14 to obtain differences between the die 14 and the corresponding die bonding area P.

In detail, after sucking the dies 14, the die sucking device 18 moves to the image capturing device 19 so that the image capturing device 19 could capture a second image of each of the dies 14. Then, through an image processing and recognizing technology, the current position and the current orientation of each of the sucked dies 14 are analyzed to further determine the differences between the current position and orientation of each of the dies 14 and the predetermined position and the predetermined orientation of the corresponding die bonding area P.

Step 106: driving the nozzles 181 to orientate the sucked dies 14.

In detail, the aiming devices 183 can move and/or rotate the nozzles 181 respectively according to the position and orientation differences between the dies 14 and the corresponding die bonding areas P so that the positions and orientations of the sucked dies 14 are consistent with the predetermined positions and the predetermined orientations of the corresponding die bonding areas P. Thereby, the sucked dies 14 can be orientated in the same manner as the die bonding areas P.

Step 108: moving the die sucking device 18 to simultaneously place the predetermined number of the dies 14 onto the substrate 17 of the second placement area 16.

In detail, the die sucking device 18 moves above the substrate 17 of the second placement area 16 and enable one of the sucked dies 14 (e.g., the first die 14A) to aim at the corresponding die bonding area P (e.g., the first die bonding area P1). When one of the sucked dies 14 aimed at the corresponding die bonding area P, all the other sucked dies 14 are also aimed at their corresponding die bonding areas P since the sucked dies 14 have already been orientated in the same manner as the die bonding areas P. Then, the suction of the nozzles 181 is released to simultaneously place the sucked dies 14 onto the die bonding areas P of the substrate 17, thus, the purpose of bonding the dies at once could be achieved thereby.

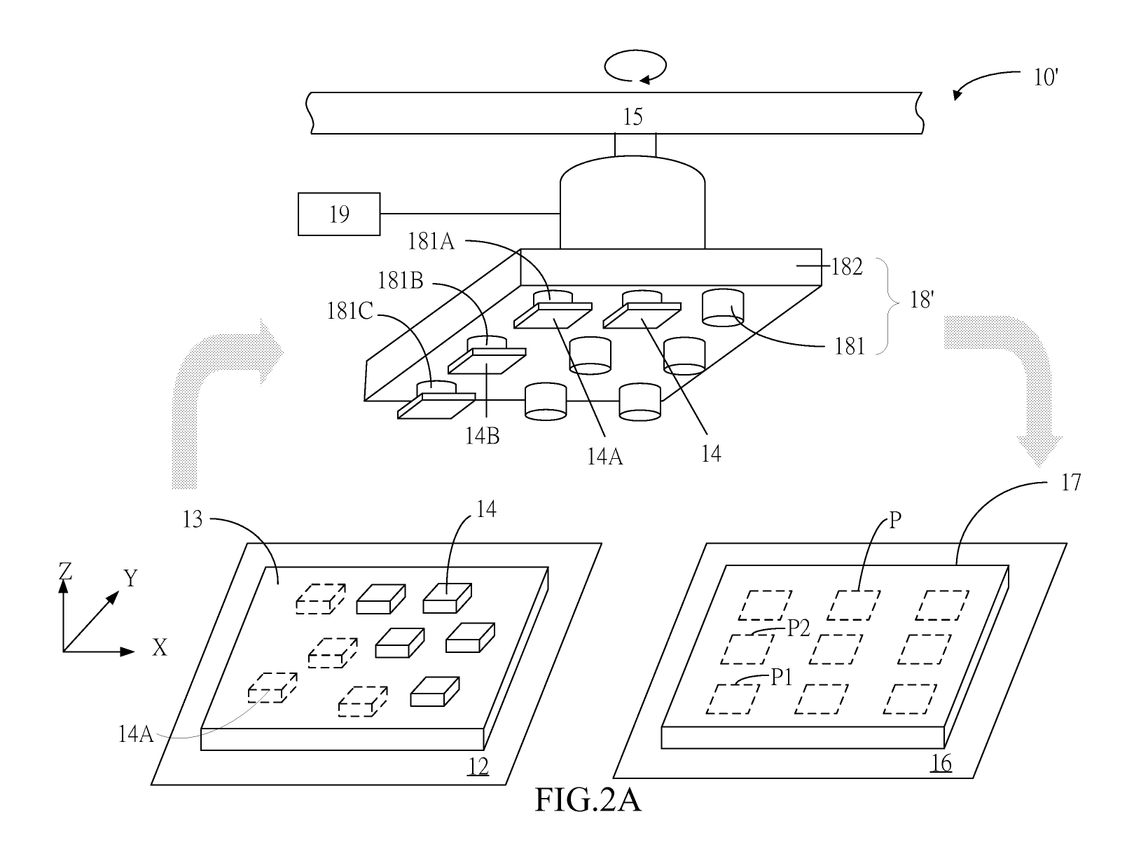

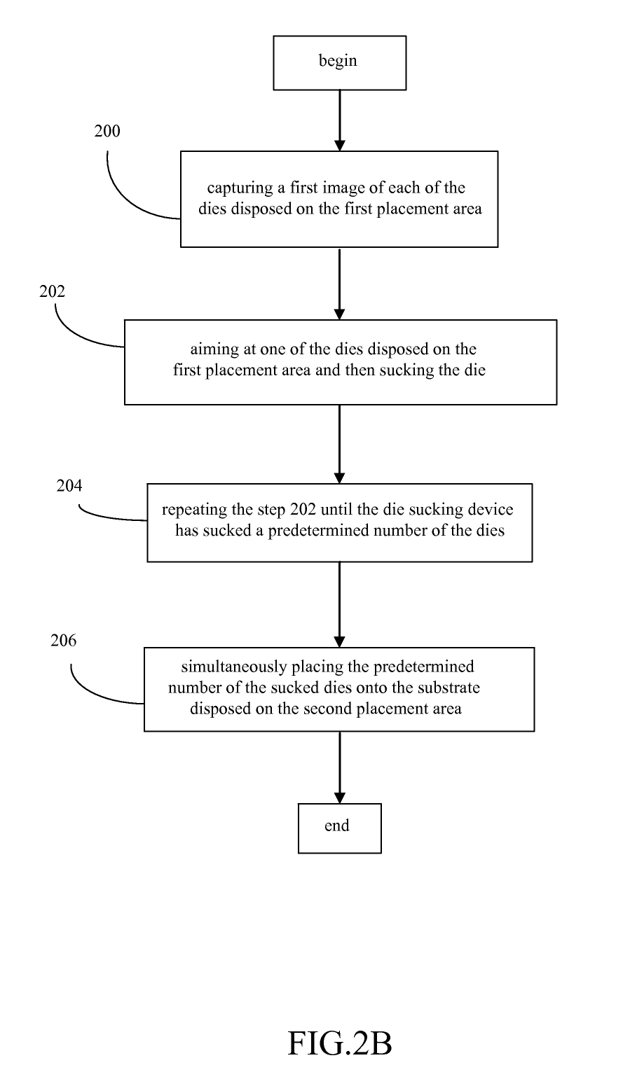

FIG. 2A illustrates a schematic view of a die bonding apparatus 10′ according to a second preferred embodiment of the present invention. The feature of the die bonding apparatus 10′ of this embodiment is that after the nozzles are aimed at the corresponding die positions respectively, the dies are sucked respectively. After all the dies have been sucked, the dies are bonded to the substrate simultaneously.

The die bonding apparatus 10′ of this embodiment differs from the die bonding apparatus 10 of the previous embodiment in that the nozzles 181 of the die sucking device 18′ of the die bonding apparatus 10′ are fixedly disposed on one side of the main body 182, so that the nozzles 181 cannot move relative to the main body 182 and cannot move relative to each other. Also, the moving device 15 of the die bonding apparatus 10′ not only can move the nozzles 181 of the die sucking device 18′ together, but also can rotate the nozzles 181 together. Because the die bonding apparatus 10′ does not need to be provided with a plurality of aiming devices 183 similar to the die bonding apparatus 10, it is easier to construct compared to the die bonding apparatus 10.

Next, FIG. 2B illustrates an operating method of the die bonding apparatus 10′, which is also the die bonding method according to the second preferred embodiment of the present invention. The die bonding method comprises the following steps:

Step 200: capturing the first image of each of the dies 14 disposed on the first placement area 12 to obtain an initial position and orientation of each of the dies 14 on the first placement area 12.

In detail, before the dies 14 on the adhesive film 13 of the first placement area 12 are sucked by the die sucking device 18′, the image capturing device 19 can capture the first image of each of the dies 14 to obtain the initial position and orientation of each of the dies 14 scattered on the first placement area 12. The initial position and orientation are used as reference indexes for the die sucking device 18′ when subsequently moving the nozzles 181 to aim at the dies 14.

Step 202: moving and/or rotating the die sucking device 18′ to aim at one of the dies 14 disposed on the first placement area 12 and then suck the die 14.

In detail, the die sucking device 18′ firstly chooses one of the nozzles 181 (e.g., the first nozzle 181A) and one of the dies 14 (e.g., the first die 14A) to be sucked by the nozzle 181. Afterwards, the position and orientation differences between the predetermined position and the predetermined orientation of the first nozzle 181A (i.e., the predetermined position and the predetermined orientation of the corresponding first die bonding area P1) and the initial position and orientation of the first die 14A to be sucked are determined

After the position and orientation differences between the first die 14A and the first nozzle 181A are obtained, the first nozzle 181A is rotated according to the orientation difference and the die sucking device 18′ is moved according to the position difference so that the first nozzle 181A is aimed at the first die 14A to suck the first die 14A. Through the aforesaid aiming and rotating operations, the position and orientation of the first die 14A sucked by the first nozzle 181A will be consistent with the predetermined position and the predetermined orientation of the corresponding first die bonding area P1.

Step 204: repeating the step 202 until the die sucking device 18′ has sucked a predetermined number of the dies 14.

In detail, after the first die 14A has been sucked, the die bonding apparatus 10′ will choose a next nozzle 181 (e.g., the second nozzle 181B) and one of the dies 14 (e.g., the second die 14B) to be sucked by the nozzle 181. Afterwards, a position difference and an orientation difference between the predetermined position and the predetermined orientation of the second nozzle 181B (i.e., the predetermined position and the predetermined orientation of the corresponding second die bonding area P2) and the initial position and orientation of the second die 14B to be sucked are determined.

Likewise, after the position and orientation differences between the second die 14B and the second nozzle 181B are obtained, the second nozzle 181B is rotated according to the orientation difference and the die sucking device 18′ is moved according to the position difference so that the second nozzle 181B aims at the second die 14B to suck the second die 14B. Through the aforesaid aiming and rotating operations, the position and orientation of the second die 14B sucked by the second nozzle 181B will be consistent with the predetermined position and the predetermined orientation of the corresponding second die bonding area P2.

Step 202 is repeated continuously until the remaining nozzles 181 of the die sucking device 18′ have all aimed at and sucked the corresponding dies 14 sequentially. In other words, through the movement and rotation of the die sucking device 18′, the position and orientation differences between each of the nozzles 181 and the die 14 to be sucked by the each of the nozzle 181 are adjusted one by one to complete the operation of sucking a predetermined number of dies 14. The dies 141 sucked by the nozzles 181 are orientated in the same manner as the die bonding areas P.

Step 206: moving the die sucking device 18′ to simultaneously place the predetermined number of the sucked dies 14 onto the substrate 17 disposed on the second placement area 16.

In detail, after the die sucking device 18′ has sucked the predetermined number of dies 14 from the first placement area 12, the die sucking device 18′ will move above the substrate 17 disposed on the second placement area 16 and enables one of the sucked dies 14 (e.g., the first die 14A) to aim at the corresponding die bonding area P (e.g., the first die bonding area P1). When the first die 14 aimed at the corresponding first die bonding area P1, the other sucked dies 14 are also aimed at the corresponding die bonding areas P since the sucked dies 14 have already been orientated in the same manner as the die bonding areas P. Afterwards, the suction of the nozzles 181 is released to simultaneously place the sucked dies 14 onto the corresponding die bonding areas P of the substrate 17, thus, the purpose of bonding the dies at once could be achieved thereby.

It shall be appreciated that a pneumatic control unit (not shown) with a plurality of control valves may also be used for the die sucking device 18′. The control valves are coupled to the nozzles 181 respectively to control the generation of the suction in the respective nozzles 181. In this way, the die sucking device 18′ of the die bonding apparatus 10′ can enable only one of the nozzles 181 to generate a suction to suck one die 14 at once.

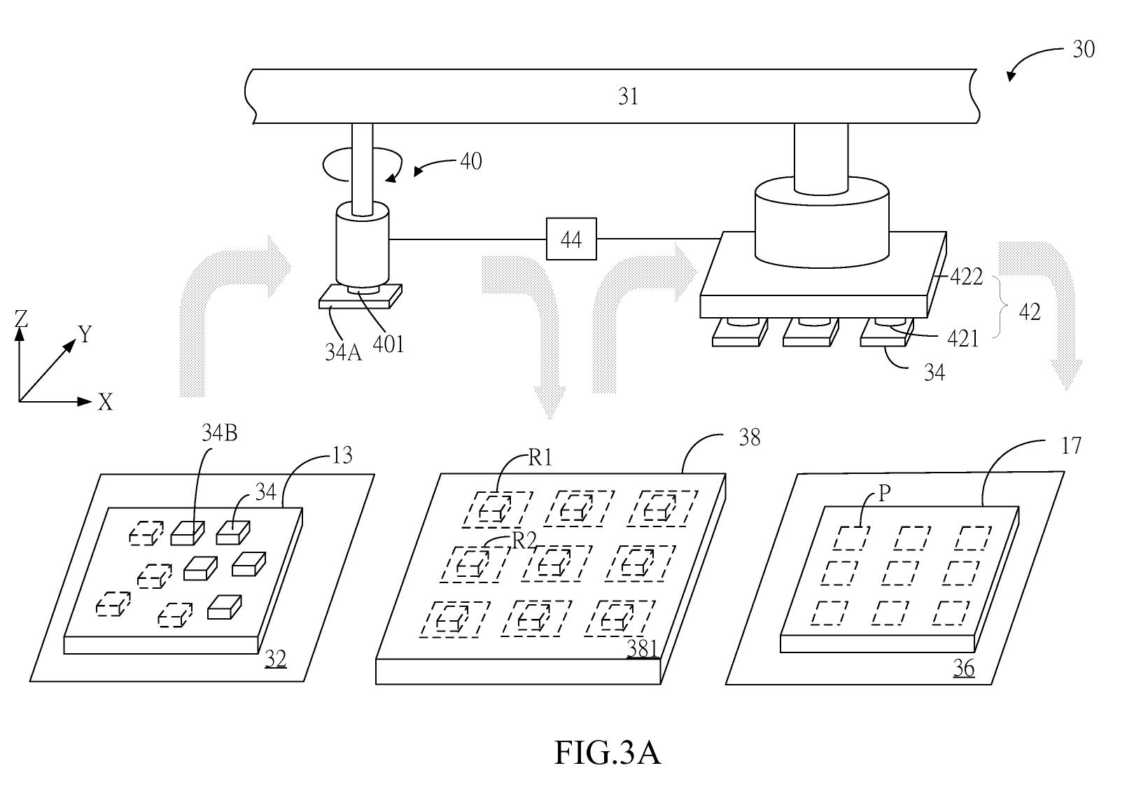

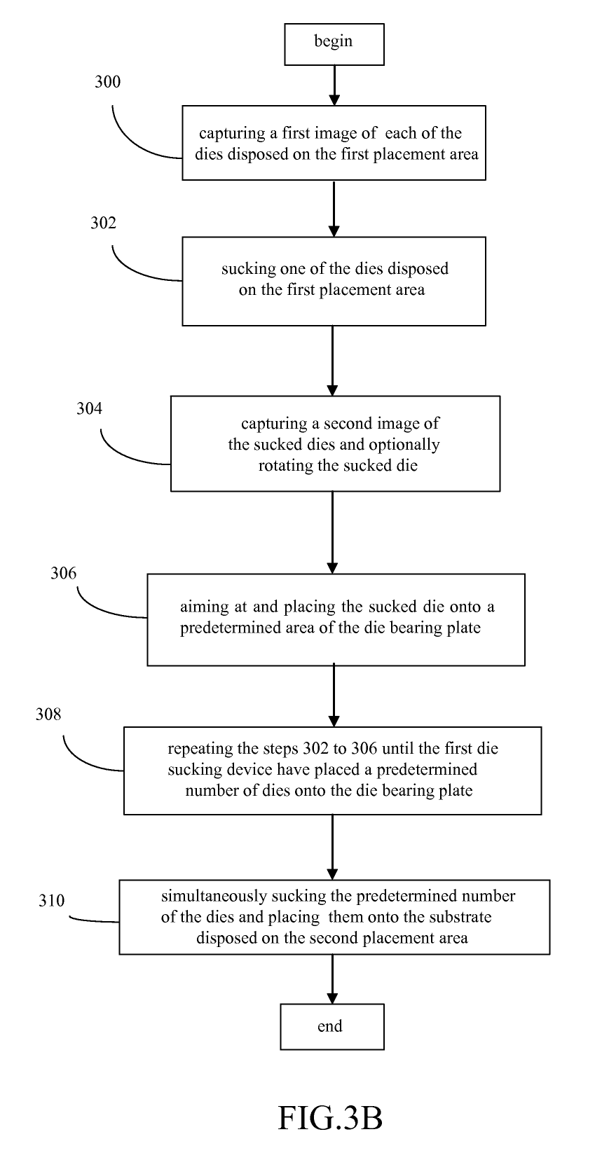

FIG. 3A illustrates a schematic view of a die bonding apparatus 30 according to a third preferred embodiment of the present invention. Similar to the previous embodiments, the die bonding apparatus 30 can also simultaneously place a predetermined number of dies 34 disposed on the first placement area 32 onto the substrate 17 disposed on the second placement area 36. Likewise, the similarities between the die bonding apparatus 30 and the die bonding apparatuses 10 and 10′ will not be further described herein.

The die bonding apparatus 30 comprises a die bearing plate 38, a first die sucking device 40, a second die sucking device 42 and an image capturing device 44, which will be further described respectively as follows.

The die bearing plate 38 is used for bearing the dies 34 thereon and can temporarily fix the dies 34. The die bearing plate 38 has a plurality of predetermined areas R defined thereon, while the substrate 17 has a plurality of die bonding areas P defined thereon. Each of the predetermined areas R and the die bonding areas P may receive one die 34 thereon. Each of the predetermined areas R corresponds to one of the die bonding areas P on the substrate 17; in other words, the predetermined areas R are orientated in the same manner as the die bonding areas P on the substrate 17 and each of the predetermined areas R defines a predetermined position and a predetermined orientation consistent with those of the corresponding die bonding area P.

The die bearing plate 38 may optionally have a vacuum suction plane 381, which is adapted to generate a suction for sucking the die 34 disposed thereon, so that the die 34 will not move easily.

The first die sucking device 40 comprises a first nozzle 401, while the second die sucking device 42 comprises a main body 422 and a plurality of second nozzles 421. The second nozzles 421 are fixedly disposed on one side of the main body 422, so that the second nozzles 421 cannot move relative to each other.

The first die sucking device 40 is movably located above the first placement area 32 and the die bearing plate 38, while the second die sucking device 42 is movably located above the second placement area 36 and the die bearing plate 38; in other words, the first die sucking device 40 can move above the first placement area 32 and the die bearing plate 38, while the second die sucking device 42 can move above the second placement area 36 and the die bearing plate 38.

Similarly, in this embodiment, the first die sucking device 40 and the second die sucking device 42 are moved by a moving device 31 respectively (e.g., a robotic arm, or a driving motor in combination with a screw). Specifically, the moving device 31 is connected to the first die sucking device 40 and the second die sucking device 42 to change horizontal positions of the first and the second die sucking devices 40, 42 by driving them to move in the X and Y directions and to change the vertical positions of the first and the second die sucking devices 40, 42 by driving them to move in the Z direction.

The image capturing device 44 may be electrically connected to and be moved relative to the first die sucking device 40 and the second die sucking device 42.

It shall be appreciated that the predetermined number of the dies 34 described in this embodiment is equal to the number of the nozzles 421 of the second die sucking device 42. For example, if the second die sucking device 42 has nine nozzles, then the predetermined number of the dies 34 is nine.

Next, FIG. 3B illustrates an operating method of the die bonding apparatus 30, which is also the die bonding method according to the third preferred embodiment of the present invention. The die bonding method comprises the following steps.

Step 300: capturing the first image of each of the dies 34 disposed on the first placement area 32 to obtain an initial position of each of the dies 34 on the first placement area 32.

In detail, before the dies 34 on the adhesive film 13 of the first placement area 32 are sucked by the first die sucking device 40, the image capturing device 44 can capture the first image of each of the dies 34. After the first image is obtained, an initial position of each of the dies 34 disposed on the first placement area 32 can be analyzed through the use of an image processing and recognizing technology.

Step 302: moving the first die sucking device 40 to suck one of the dies 34 disposed on the first placement area 32.

In detail, after the initial position of each of the dies 34 is obtained, the first die sucking device 40 is moved above one of the dies 34 (e.g., the first die 34A) so that the first nozzle 401 is aimed at and then sucks the first die 34A.

Step 304: capturing the second image of the sucked die 34 and optionally rotating the sucked die 34.

In detail, after the die 34 (e.g., the first die 34A) has been sucked by the first nozzle 401, the image capturing device 44 can capture the second image of the first die 34A to analyze the current orientation of the first die 34A through the use of an image processing and recognizing technology. If a difference exists between the current orientation of the first die 34A and a predetermined orientation of a predetermined area R (e.g., the first predetermined area R1) on which the first die 34A is to be disposed, then the moving device 31 may further rotate the first nozzle 401 to make the orientation of the first die 34A consistent with the predetermined orientation of the first predetermined area R1.

Step 306: aiming at and placing the sucked die 34 onto the predetermined area R of the die bearing plate 38.

In detail, the first die sucking device 40 will move above the die bearing plate 38 in such a way that the first die 34A is aimed at the first predetermined area R1 on which the first die 34A is to be disposed, and afterwards the suction of the first nozzle 401 is released so as to place the first die 34A onto the first predetermined region R1.

In this step, if the position information of the first predetermined area R1 is not obtained in advance, then an image of the first predetermined area R1 may be captured by the image capturing device 44 to obtain the position information of the first predetermined area R1. Then, the first die sucking device 40 is moved according to the position information obtained from the image so as to enable the first nozzle 401 to aim at and place the first die 34A onto the first predetermined area R1.

Step 308: repeating the steps 302 to 306 until the first die sucking device 40 have placed a predetermined number of dies 34 onto the die bearing plate 38.

In detail, when one of the dies 34 has been placed onto the predetermined area R, the first sucking device 40 will move back above the first placement region 32 to suck another die 34 (e.g., the second die 34B). Then, the first sucking device 40 can optionally adjust an orientation of the sucked die 34 to make it consistent with the predetermined orientation of the corresponding predetermined area R (e.g., the second predetermined area R2). Next, the first sucking device 40 will move above die bearing plate 38 so that the sucked die 34 is aimed at and then placed onto the predetermined area R.

By repeating the aforesaid operations, the first die sucking device 40 can make a predetermined number of dies 34 disposed on the first placement area 32 aimed at and placed onto the predetermined areas R of the die bearing plate 38 sequentially.

Step 310: moving the second die sucking device 42 to simultaneously suck the predetermined number of dies 34 from the die bearing plate 38 and place them onto the substrate 17 disposed on the second placement area 36.

In detail, the dies 34 disposed on the predetermined areas R of the die bearing plate 38 actually are already orientated in the same manner as the die bonding areas P of the substrate 17 since the die bonding areas P of the substrate 17 are orientated in the same way as the predetermined areas R of the die bearing plate 38 (i.e., they have the same positions and orientations).

In this case, the second die sucking device 42 only needs to move above the die bearing plate 38 and enables the second nozzles 421 to simultaneously suck the dies 34 disposed on the predetermined areas R. Then, the moving device 31 will move the second die sucking device 42 to the substrate 17 disposed on the second placement area 36, and move and/or rotate the second die sucking device 42 according to the difference between one of the sucked dies 34 and the corresponding die bonding area P so that the one of the sucked dies 34 is aimed at the corresponding die bonding area P. When the one of the sucked dies 34 aimed at the corresponding die bonding area P, all the other sucked dies 34 are also aimed at their corresponding die bonding areas P respectively since the sucked dies 34 have already been orientated in the same manner as the die bonding areas P. Afterwards, the sucked dies 34 are simultaneously placed onto the die bonding areas P of the substrate 17, thus, the purpose of bonding the dies at once could be achieved thereby.

The die bonding apparatus and the die bonding method of the present invention have the following features:

1. The die bonding apparatus of the present invention can simultaneously place a plurality of dies onto a substrate, which can significantly reduce the amount of die bonding time as compared to the prior art.

2. The die bonding apparatus of the present invention utilizes a die sucking device(s) to suck and place the dies, such that the positional accuracy of sucking and placing the dies is improved.

3. The die bonding apparatus of the present invention can orientate the sucked dies so that the dies can be simultaneously placed onto the corresponding die bonding areas, thus, the purpose of bonding the dies at once could be achieved thereby. The die bonding apparatus of the present invention may eliminate the need of repeated heating steps as required in the conventional die bonding process, and the thermal budget could be reduced and the quality of dies could be improved thereby.

4. The die bonding method of the present invention can simultaneously fix a plurality of dies onto a substrate, and is not limited to be executed by the die bonding apparatus disclosed in the present invention.

The above disclosure is related to the detailed technical contents and inventive features thereof. People skilled in this field may proceed with a variety of modifications and replacements based on the disclosures and suggestions of the invention as described without departing from the characteristics thereof. Nevertheless, although such modifications and replacements are not fully disclosed in the above descriptions, they have substantially been covered in the following claims as appended.

What is claimed is:

1. A die bonding apparatus for bonding a plurality of dies from a first placement area onto a substrate disposed on a second placement area, the die bonding apparatus comprising:
a die sucking device movably located above the first placement area and the second placement area, wherein the die sucking device comprises a plurality of nozzles;
wherein the nozzles are used for sucking a predetermined number of the dies disposed on the first placement area and then simultaneously placing the predetermined number of the dies onto the substrate.

2. The die bonding apparatus of claim 1, further comprising a moving device connected to the die sucking device for moving the die sucking device, wherein the die sucking device further comprises:
a main body, wherein the nozzles are disposed on one side of the main body; and
a plurality of aiming devices disposed inside of the main body and respectively coupled to the nozzles, wherein each of the aiming devices is used for moving and/or rotating the coupled nozzle respectively.

3. The die bonding apparatus of claim 1, further comprising a moving device connected to the die sucking device for moving and/or rotating the die sucking device, wherein the die sucking device further comprises a main body, and the nozzles are fixedly disposed on one side of the main body.

4. The die bonding apparatus of claim 2, further comprising an image capturing device electrically connected to the die sucking device for capturing an image of each of the dies.

5. The die bonding apparatus of claim 3, further comprising an image capturing device electrically connected to the die sucking device for capturing an image of each of the dies.

6. A die bonding apparatus for bonding a plurality of dies from a first placement area onto a substrate disposed on a second placement area, the die bonding apparatus comprising:
a die bearing plate;
a first die sucking device movably located above the first placement area and the die bearing plate, wherein the first die sucking device comprises a first nozzle; and
a second die sucking device movably located above the second placement area and the die bearing plate, wherein the second die sucking device comprises a plurality of second nozzles;
wherein the first nozzle is used for sucking one of the dies disposed on the first placement area and aiming at the die bearing plate to place the sucked die onto the die bearing plate until the first die sucking device has placed a predetermined number of the dies onto the die bearing plate; and the second nozzles are used for simultaneously sucking the predetermined number of the dies disposed on the die bearing plate and simultaneously placing the predetermined number of the dies onto the substrate.

7. The die bonding apparatus of claim 6, further comprising a moving device connected to the first die sucking device for moving and/or rotating the first die sucking device.

8. The die bonding apparatus of claim 6, further comprising a moving device connected to the second die sucking device for moving the second die sucking device, wherein the second die sucking device further comprises a main body, and the second nozzles are fixedly disposed on one side of the main body.

9. The die bonding apparatus of claim 7, further comprising an image capturing device electrically connected to the first die sucking device and the second die sucking device for capturing an image of each of the dies sucked by the first nozzle.

10. The die bonding apparatus of claim 6, wherein the die bearing plate has a vacuum suction surface.

11. A die bonding method for bonding a plurality of dies from a first placement area onto a substrate disposed on a second placement area, the method comprising:
moving a die sucking device to aim at one of the dies disposed on the first placement area and then to suck the one of the dies;
repeating the above step until the die sucking device has sucked a predetermined number of the dies; and
moving the die sucking device to simultaneously place the predetermined number of the dies onto the substrate disposed on the second placement area.

12. The die bonding method of claim 11, wherein the step of moving the die sucking device further comprises:
capturing an image of each of the dies disposed on the first placement area by an image capturing device; and
moving the die sucking device according to the image so as to aim at and suck the one of the dies disposed on the first placement area.

13. A die bonding method for bonding a plurality of dies from a first placement area onto a substrate disposed on a second placement area, the method comprising:
moving a die sucking device having a plurality of nozzles to suck a predetermined number of the dies disposed on the first placement area;
driving the nozzles to orientate the predetermined number of the dies sucked by the nozzles; and
moving the die sucking device to simultaneously place the predetermined number of the dies onto the substrate disposed on the second placement area.

14. The die bonding method of claim 13, wherein the step of driving the nozzles further comprises:
capturing an image of each of the sucked dies by an image capturing device; and
driving each of the nozzles of the die sucking device to aim at a predetermined orientation corresponded to each of the sucked dies according to the images thereof.

15. A die bonding method for bonding a plurality of dies from a first placement area onto a substrate disposed on a second placement area, the method comprising:
moving a first die sucking device to suck one of the dies disposed on the first placement area;
aiming at a predetermined area of a die bearing plate and placing the sucked die onto the predetermined area of the die bearing plate;
repeating the above steps until the first die sucking device has placed a predetermined number of the dies onto the die bearing plate; and
moving a second die sucking device to simultaneously suck the predetermined number of the dies disposed on the die bearing plate and simultaneously place the predetermined number of the dies onto the substrate disposed on the second placement area.

16. The die bonding method of claim 15, wherein the step of aiming and placing the sucked die further comprises:
capturing an image of the predetermined area of the die bearing plate by an image capturing device; and
moving the first die sucking device to aim at the predetermined area and place the sucked die onto the predetermined area according to the image.
